(19) United States
(12) Patent Application Publication
(10) Pub. No.: US 2024/0069592 A1
(43) Pub. Date: Feb. 29, 2024

(54) STAGGERED MATERIALS CORNER STRUCTURE FOR ELECTRONIC DEVICE ENCLOSURE

(71) Applicant: Hewlett-Packard Development Company, L.P., Spring, TX (US)

(72) Inventors: Wen-Chih Chen, Taipei City (TW); Po-Feng Chuang, Taipei City (TW)

(21) Appl. No.: 17/899,902

(22) Filed: Aug. 31, 2022

(51) Int. Cl. G06F 1/16; H05K 5/04

(52) U.S. Cl. CPC G06F 1/1616; H05K 5/04

(57) ABSTRACT

An enclosure for an electronic device has a staggered materials corner structure. The enclosure includes an integral metal frame defining exterior sides of the enclosure. The integral metal frame has a tab inset and not visible at a corner of the enclosure. The enclosure includes either or both of first and second materials molded around the tab. The tab of the integral metal frame and either or both of the first and second materials define the staggered materials corner structure of the enclosure.

### BACKGROUND

Electronic devices can be portable. Examples of portable electronic devices including portable computing devices, such as laptop and notebook computers, smartphones, tablet computing devices, and so on. Electronic devices can have one or multiple enclosures, or housings, in which internal components are disposed, such as logic boards, integrated circuits (ICs), and so on. A user physically handles an electronic device at its enclosure or enclosures. For example, a user may carry a laptop or notebook computer after first closing its upper and lower housings together, and then grasping onto the closed housings.

### BRIEF DESCRIPTION OF THE DRAWINGS

FIGS. 1A, 1B, and 1C are diagrams of example electronic device enclosures.

FIGS. 2A, 2B, 2C, 2D and 2E are diagrams of an example staggered materials corner structure of an electronic device enclosure.

FIG. 3 is a diagram of example stiffness zones of a staggered materials corner structure of an electronic device enclosure.

FIG. 4 is a flowchart of an example method for manufacturing an electronic device enclosure having a staggered materials corner structure.

FIGS. 5A, 5B, 5C, and 5D are diagrams of example manufacture of an electronic device enclosure having a staggered materials corner structure.

### DETAILED DESCRIPTION

As noted in the background, an electronic device may have one or multiple enclosures. The enclosures may be fabricated from a rigid, hard material, such as a metal like aluminum, titanium, magnesium, or an alloy thereof. Particularly for electronic devices that are portable and therefore frequently carried, it is not unusual for an electronic device to be dropped or fall. It is further not unusual that when an electronic device is dropped or falls, the device makes impact at a corner of its enclosure.

Because the enclosure may be fabricated from a rigid and hard material, the result of such corner impact is that the enclosure may become damaged. For example, the enclosure may become cracked, bent, or otherwise physically deformed at the impact corner. At best, such damage may just be aesthetic in nature. However, in more serious cases, the impact force may be transferred inwards to and damage the interior components of the device. The electronic device may not longer be operable.

Techniques described herein provide for a staggered materials corner structure for an electronic device enclosure that ameliorate these shortcomings. The staggered materials structure is made up of multiple, different materials that are arranged in a staggered manner at a corner of the enclosure. The structure has multiple stiffness zones ordered from the exterior and proceeding inwards. The materials are selected and the structure configured to maintain appearance and shape integrity upon corner impact, and to absorb impact force that may otherwise damage interior device components.

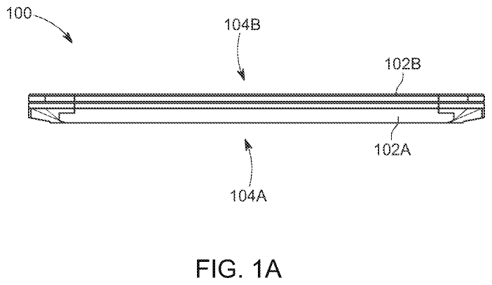

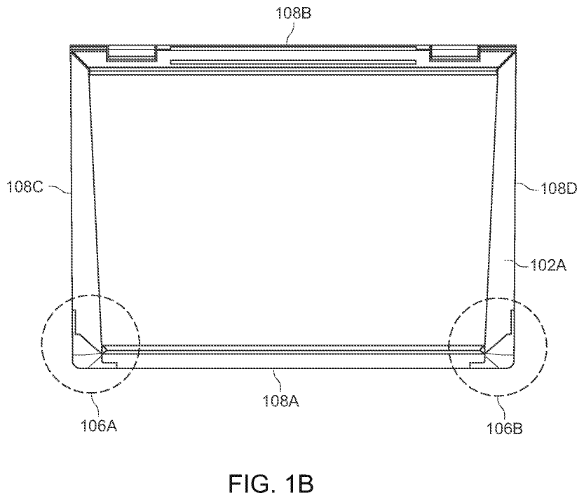

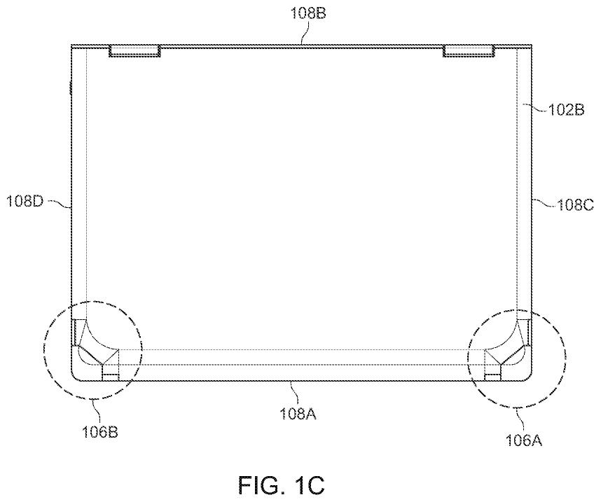

FIGS. 1A, 1B, and 1C show a lower enclosure 102A and an upper enclosure 102B of an electronic device 100. FIG. 1A shows a front view of the electronic device 100. FIG. 1B shows the bottom view of the lower enclosure 102A per the arrow 104A of FIG. 1A. FIG. 1C shows the top view of the upper enclosure 102B per the arrow 104B of FIG. 1A. The enclosures 102A and 102B have staggered materials corner structures 106A and 106B at two of their four corners. In another implementation, the enclosures 102A and 102B may have staggered materials corner structures at more than two corners, at different two of the corners, or at one corner. The electronic device 100 has front and back sides 108A and 108B and right and left sides 108C and 108D.

In the depicted example, the electronic device 100 is a portable computer, such as a laptop or notebook computer. For instance, the upper enclosure 102B may house a display screen and be rotatable relative to the lower enclosure 102A that may house a keyboard and a pointing device such as a touchpad. The enclosures 102A and 102B are depicted in the closed position in FIG. 1A, and may be rotated to an opened position for usage of the keyboard, pointing device, and the display screen. In other implementations, the device 100 may not be a portable computer or other portable device, and may have just one enclosure or more than two enclosures. For example, the electronic device 100 may instead by a desktop computer, an all-in-one (AIO) computer that includes a built-in display, an external display device for a computer, and so on.

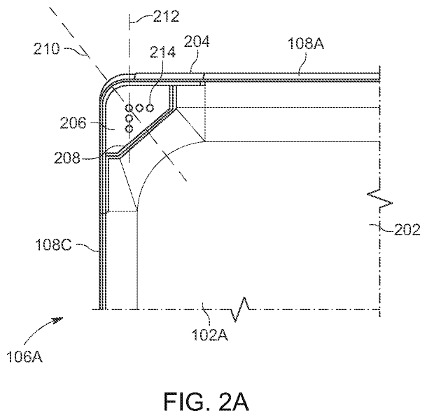

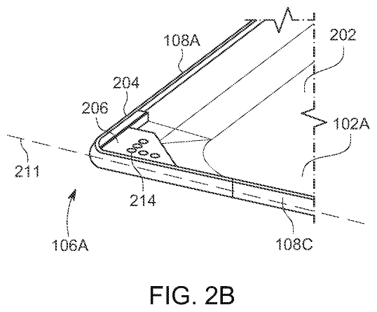

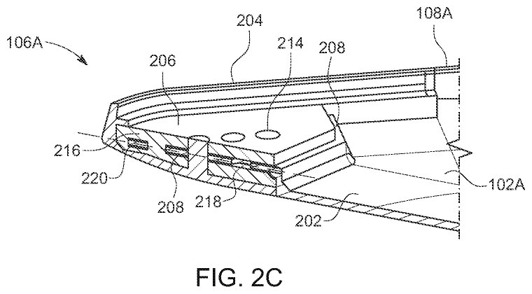

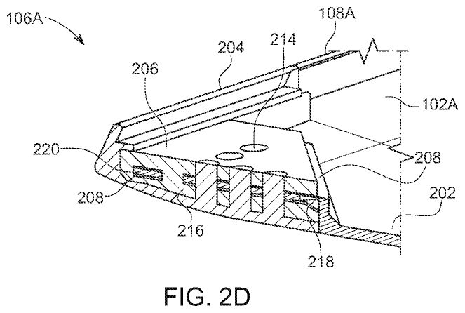

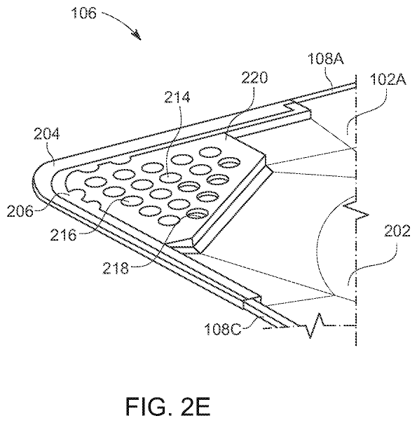

FIGS. 2A, 2B, 2C, 2D, and 2E show the example staggered materials corner structure 106A of the lower enclosure 102A where the sides 108A and 108C meet. The staggered materials corner structure 106B of the lower enclosure 102A, and the staggered materials corner structures 106A and 106B of the upper enclosure 102B, may be implemented similarly. FIGS. 2A and 2B show top and perspective views, respectively, of the corner structure 106A. FIGS. 2C and 2D show cross-sectional views at the cross-sectional lines 210 and 212 of FIG. 2A, respectively. FIG. 2E shows a cross-sectional view at the cross-sectional line 211 of FIG. 2B.

The lower enclosure 102A includes an integral metal frame 202 that defines the exterior sides 108A and 108C of the enclosure 102A except at the corner where the sides 108A and 108C meet. The integral metal frame 202 is integral in that it is fashioned from a single piece of metal, such as via stamping, machining, casting, and/or extrusion, or from multiple pieces of metal fused or otherwise joined together. Examples of the metal employed include aluminum, titanium, magnesium, and alloys thereof.

The staggered materials corner structure 106A includes a first material 204 and a second material 206. In another implementation, the structure 106A may include just the first material 204 or just the second material 206. The materials 204 and 206 are formed via respective molding processes, such as over-molding or insert-molding. The first material 204 is softer than the second material 206; that is, the second material is harder than the first material 204.

The first material 204 may have a hardness between 80 and 95 on a Shore A scale, and may be thermoplastic polyurethane (TPU). The second material 206 may be a plastic material having a hardness of greater than 60 on a Shore D scale. In the depicted implementation, the first material 204 defines the exterior sides 108A and 108C at the corner, and is thus flush with the integral metal frame 202. The first material 204 is therefore visible at the corner, whereas the second material 206 is not since it is surrounded by the first material 204.

The staggered materials corner structure 106A includes a tab 220 extending from the integral metal frame 202, as best depicted in FIG. 2E. The second material 206 is molded around the tab 220, and the first material 204 is molded around both the tab 220 and the second material 206, as best depicted in FIGS. 2C and 2D. The tab 220 is inset at the corner where the exterior sides 108A and 108C meet, and is not visible at the corner since it is surrounded by the materials 204 and 206.

The tab 220 and the materials 204 and 206 are disposed in a staggered manner, thus defining the staggered materials corner structure 106A. That is, from a planar perspective and starting at the exterior of the corner where the exterior sides 108A and 108C meet, the first material 204 is positioned first, followed by the second material 206 and then the tab 220, as best depicted in FIG. 2E. Perpendicular to the plane of the planar perspective, and starting from the bottom of the enclosure 102A, the first material 204 is positioned first, followed by the second material 206, then the tab 220, and finally the second material 206 again, as best depicted in FIGS. 2C and 2D.

The tab 220 includes first through-holes 214 and 216 and/or second through-holes 218. The through-holes 214, 216, and 218 extend through the entire tab 220. The through-holes 214 are depicted in all the FIGS. 2A-2E. The through-holes 216 are depicted in FIGS. 2D and 2E, and the through-holes 218 are depicted in FIGS. 2C and 2E. During molding over the tab 220, the second material 206 extends through and fills the through-holes 216. During molding over the tab 220 and the second material 206, the first material 204 extends through and fills the through-holes 214. The presence of the through-holes 214 and 216 aids in molding of the materials 204 and 206, respectively, over the tab 220, and in securing the materials 204 and 206 within the structure 106A.

In the implementation in which the tab 220 includes the second through-holes 218, the staggered materials corner structure 106A can include a plastic film 208 applied to the bottom and top surfaces of the tab 220 to cover the through-holes 218 (but not the through-holes 214 and 216) prior to molding of the materials 206 and 204 over the tab 220. The plastic film 208 may be polyethylene terephthalate, which is available under the trademark MYLAR. Because the plastic film 208 is applied prior to molding of the materials 206 and 204 over the tab 220, the film 208 defines air pockets at the through-holes 218 that are unfilled (and thus not filled by either material 204 or 206).

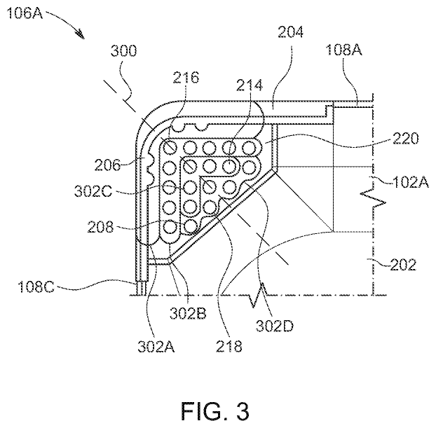

FIG. 3 shows a non-perspective view of the same cross-section of the staggered materials corner structure 106A as in FIG. 2E. The through-holes 216 filled by the second material 206 are closest to the corner where exterior sides 108A and 108C of the enclosure 102A meet. The through-holes 214 filled by the first material 204 are interior to the through-holes 216, whereas the through-holes 218 that are not filled by either material 204 or 206 are most interior of the through-holes 214, 216, and 218. The staggered materials corner structure 106A has example stiffness zones 302A, 302B, 302C, and 302D ordered from the corner where the exterior sides 108A and 108C meet and proceeding inwards into the interior of the enclosure 102A.

The stiffness zone 302A is defined primarily by the first material 204 at the exterior sides 108A and 108C at the corner. Because the first material 204 is relatively soft, the stiffness zone 302A is deformable, such that the zone 302A maintains visual appearance and shape integrity of the enclosure 102A upon corner impact. That is, if the enclosure 102A is dropped or falls and makes impact at the corner structure 106A, the structure 106A may temporarily deform but not permanently crack or become bent in the zone 302A, such that the visual appearance and the shape of the structure 106A is maintained at the zone 302A.

The stiffness zone 302B inward of the stiffness zone 302A is defined primarily by the through-holes 216 of the tab 220 filled by the second material 206, and thus by the tab 220 and the second material 206. Because the second material 206 is rigid and relatively hard, the stiffness zone 302B maintains rigidity of the enclosure 102A upon corner impact. That is, if the enclosure 102A is dropped or falls and makes impact at the corner structure 106A, the rigidity of the enclosure 102A is maintained at the zone 302B.

The stiffness zone 302C inward of the stiffness zone 302B is defined primarily by the through-holes 214 of the tab 220 filled by the first material 204, and thus by the tab 220 and the first material 204. Because the first material 204 is relatively soft, the stiffness zone 302C absorbs impact energy upon corner impact. That is, if the enclosure 102A is dropped or falls and makes impact at the corner structure 106A, the impact energy may be at least partially absorbed at the zone 302C and not be transferred further inward towards the interior of the enclosure 102A. Therefore, damage to components of the electronic device 100 in the interior can be prevented.

The stiffness zone 302D inward of the stiffness zone 302C is defined primarily by the through-holes 218 of the tab 220 not filled by either material 204 or 206, and thus by the tab 220 and the air pockets defined by the through-holes 218. Since the through-holes 218 are not filled by any material 204 or 206, the stiffness zone 302D also absorbs impact energy upon corner impact. That is, if the enclosure 102A is dropped or falls and makes impact at the corner structure 106A, the impact energy may also be at least partially absorbed at the zone 302D and not be transferred further inwards where the energy may damage components of the electronic device 100 in the interior.

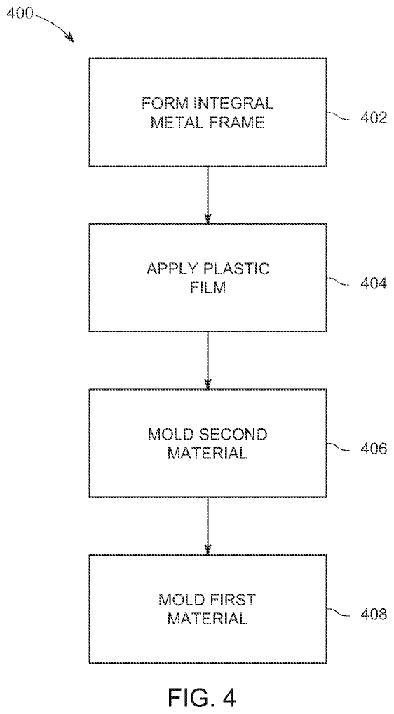

FIG. 4 shows an example method 400 for manufacturing the enclosure 102A to include the staggered materials corner structure 106A. The corner structure 106B of the enclosure 102A can be manufactured at the same time. The method 400 can similarly be performed for manufacturing the enclosure 102B to include the staggered materials corner structure 106A and/or 106B.

The method 400 includes forming the integral metal frame 202 of the enclosure 102A (402). The metal frame 202 may be stamped, machined, extruded, and/or cast. In the case of machining, the metal frame 202 may be machined using a computer numerical control (CNC) machining process. A two-dimensional (2D) sheet of metal can thus be transformed into the three-dimensional (3D) shape of the metal frame 202, including the tab 220 extending from the frame 202 with its through-holes 214, 216, and 218.

The method 400 can include then applying a plastic film to the top and bottom surfaces of the tab 220 over the through-holes 218 (but not the through-holes 214 and 216) so that during subsequent molding of the materials 204 and 206, the through-holes 218 will not be filled by either material 204 and 206 (404). The method 400 can include molding the second material 206 around the tab 220 and through the through-holes 216 (406), and then molding the first material 204 around the molded second material 206 and the tab 220 and through the through-holes 214 (408).

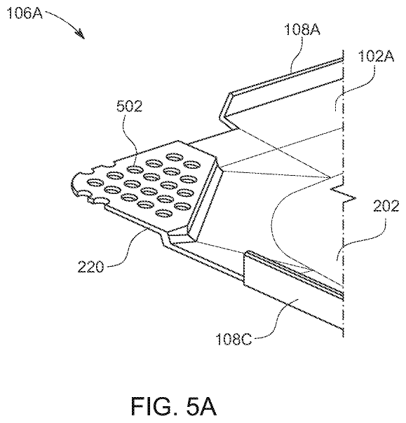

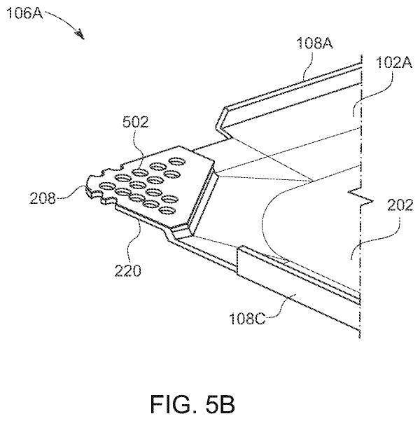

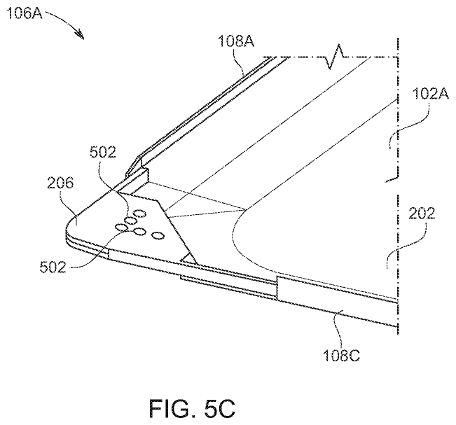

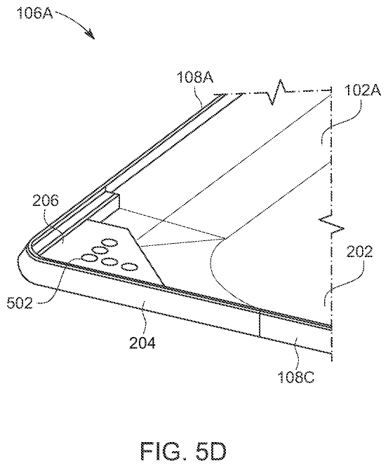

FIGS. 5A, 5B, 5C, and 5D depict example manufacture of the staggered materials corner structure 106A of the enclosure 102A in accordance with the method 400. In FIG. 5A, the integral metal frame 202 of the enclosure 102A is formed, including the tab 220 inset at the corner defined by the exterior sides 108A and 108C and including the through-holes 502 extending through the tab 220. The through-holes 502 corresponds to all the through-holes 214, 216, and 218 that have been referenced above.

In FIG. 5B, a plastic film 208 is applied to the top and bottom surfaces of the tab 220 to cover some of the through-holes 502, particularly those corresponding to the through-holes 218 that have been referenced above. In FIG. 5C, the second material 206 is molded around the tab 220 to fill other of the through-holes 502, particularly those corresponding to the through-holes 216 that have been referenced above. Molding the second material 206 through these through-holes 502 aids in the molding process, and secures the material 206 to the metal tab 220.

Finally, in FIG. 5D, the first material 206 is molded around the second material 206 (and the tab 220) to fill the remaining of the through-holes 502, which correspond to the through-holes 214 referenced above. Molding the first material 204 through these through-holes 502 aids in the molding process, and secures the material 204 to the second material 206 and to the metal tab 220. The first material 206 is molded to define the exterior sides 108A and 108C at the corner of the enclosure 102A, and is flush with the integral metal frame 202 at the exterior sides 108A and 108C.

An enclosure 102A for an electronic device 100 has been described that has a staggered materials corner structure 106A. The corner structure 106A is made up of a metal tab 220 and materials 104 and/or 106 that are staggered in position. The staggered configuration of the corner structure 106A and the different materials 104 and/or 106 help define different stiffness zones 302A, 302B, 302C, and/or 302D that can have different functions upon corner impact of the enclosure 102. At corner impact, the enclosure 102A is more likely to maintain its appearance and shape at the impacted corner, with decreased likelihood that interior components of the device 100 will become damaged.

We claim:

1. An enclosure for an electronic device having a staggered materials corner structure, comprising:
an integral metal frame defining exterior sides of the enclosure, the integral metal frame having a tab inset and not visible at a corner of the enclosure; and
either or both of first and second materials molded around the tab,
wherein the tab of the integral metal frame and either or both of the first and second materials define the staggered materials corner structure of the enclosure.

2. The enclosure of claim 1, comprising both the first and second materials,
wherein the first material is softer than the second material.

3. The enclosure of claim 2, wherein the first material comprises a thermoplastic polyurethane material having a hardness between 80 and 95 on a Shore A scale,
and wherein the second material comprises a plastic material having a hardness of greater than 60 on a Shore D scale.

4. The enclosure of claim 2, wherein the first material is molded around the second material as well as around the tab,
wherein the second material is not visible at the corner of the enclosure,
and wherein the first material defines the exterior sides of the enclosure at the corner, is flush with the integral metal frame at the exterior sides of the enclosure, and is visible at the corner of the enclosure.

5. The enclosure of claim 2, wherein the tab of the integral metal frame has a plurality of first through-holes,
wherein the first material is molded through and fills some of the first through-holes,
and wherein the second material is molded through and fills the first through-holes through which the first material is not molded and that the first material does not fill.

6. The enclosure of claim 5, wherein the tab of the integral metal frame further has a plurality of second through-holes different than the first through-holes, the enclosure further comprising:
a plastic film on each of bottom and top surfaces of the tab of the integral metal frame and covering the second through-holes but not the first through-holes to define air pockets at the second through-holes.

7. The enclosure of claim 6, wherein the plastic film comprises a polyethylene terephthalate film.

8. The enclosure of claim 1, comprising just the second material and not the first material,
wherein the second material comprises a plastic material having a hardness of greater than 60 on a Shore D scale.

9. The enclosure of claim 8, wherein the tab of the integral metal frame comprises a plurality of first through-holes,
and wherein the second material is molded through and fills at least some of the first through-holes.

10. The enclosure of claim 9, wherein the tab of the integral metal frame further has a plurality of second through-holes different than the first through-holes, the enclosure further comprising:
a plastic film on each of bottom and top surfaces of the tab of the integral metal frame and covering the second through-holes but not the first through-holes to define air pockets at the second through-holes.

11. The enclosure of claim 1, comprising just the first material and not the second material,
wherein the first material comprises a thermoplastic polyurethane material having a hardness between 80 and 95 on a Shore A scale.

12. The enclosure of claim 11, wherein the tab of the integral metal frame comprises a plurality of first through-holes,
and wherein the first material is molded through and fills at least some of the first through-holes.

13. The enclosure of claim 12, wherein the tab of the integral metal frame further has a plurality of second through-holes different than the first through-holes, the enclosure further comprising:
a plastic film on each of bottom and top surfaces of the tab of the integral metal frame and covering the second through-holes but not the first through-holes to define air pockets at the second through-holes.

14. An electronic device comprising:
an enclosure having a staggered materials structure with multiple stiffness zones at a corner of the enclosure, the multiple stiffness zones ordered from an exterior of the corner of the enclosure and proceeding inwards into an interior of the corner.

15. The electronic device of claim 14, wherein the staggered materials structure comprises:
a first material at the exterior of the corner of the enclosure and defining a first stiffness zone that is deformable, the first stiffness zone maintaining appearance and shape integrity of the enclosure upon corner impact.

16. The electronic device of claim 15, wherein the staggered materials structure further comprises:
a tab of an integral metal frame, the tab having a plurality of first through-holes;
a second material harder than the first material, molded around the tab, and molded through and filling the first through-holes closest to the exterior of the corner of the enclosure,
and wherein the tab and the second material filling the first through-holes define a second stiffness zone inward of the first stiffness zone, the second stiffness zone maintaining rigidity of the enclosure upon corner impact.

17. The electronic device of claim 16, wherein the first material is molded around the tab and the second material and is molded through and fills the first through-holes not filled through which the second material is not molded and that the second material does not fill,
and wherein the tab and the first material filling the first through-holes defines a third stiffness zone inward of the second stiffness zone, the third stiffness zone absorbing impact energy upon corner impact.

18. The electronic device of claim 17, wherein the tab further has a plurality of second through-holes that are unfilled and that define air pockets,
and wherein the tab and the air pockets defined by the second through holes define a fourth stiffness zone inward of the third stiffness zone, the fourth stiffness zone also absorbing the impact energy upon corner impact.

19. A method comprising:
forming an integral metal frame of an enclosure for an electronic device, the integral metal frame defining exterior sides of the enclosure and having a tab inset at a corner of the enclosure, the tab having a plurality of first through-holes;
molding a second material around the tab and through some of the first through-holes; and
molding a first material softer than the second material around the tab, around the second material, and through the first through-holes through which the second material is not molded, the first material defining the exterior sides of the enclosure at the corner and is flush with the integral metal frame at the exterior sides of the enclosure.

20. The method of claim 19, wherein the tab further has a plurality of second-through holes, the method further comprising:
applying a plastic film on each of bottom and top surfaces of the tab of the integral metal frame to cover the second through-holes but not the first through-holes, prior to molding the second material and the first material, to define air pockets at the second through-holes.
